(19) United States
(12) Patent Application Publication
(10) Pub. No.: US 2021/0280997 A1
(43) Pub. Date: Sep. 9, 2021

(54) CO-LOCATED RIGHT ANGLE AND VERTICAL CONNECTOR PADS

(71) Applicant: Hewlett-Packard Development Company, L.P., Spring, TX (US)

(72) Inventor: Ricardo Osuna, Boise, ID (US)

(73) Assignee: Hewlett-Packard Development Company, L.P., Spring, TX (US)

(21) Appl. No.: 17/256,488

(22) PCT Filed: Nov. 14, 2018
(86) PCT No.: PCT/US2018/060957

§ 371 Date: Dec. 28, 2020

(51) Int. Cl. H01R 12/55; H05K 1/11; B41J 29/38

(52) U.S. Cl. CPC H01R 12/55; H05K 2201/09409; B41J 29/38; H05K 1/117

(57) ABSTRACT

In example implementations, a printed circuit assembly (PCA) is provided. The PCA includes vertical connector pads and right angle connector pads. The vertical connector pads includes a first row of pads and a second row of pads. The right angle connector pads include the first row of pads of the vertical connector pads and additional pads located between adjacent pads of the first row of pads of the vertical connector pads.

### BACKGROUND

Printing circuit assemblies (PCAs) may interconnect to other components using flat flexible cables (FFC). One example of a system that uses PCAs may be a printing device. Printing devices can be used to print text, images, and the like on print media. Printers may include a formatter or a circuit board that is used to process information. The formatter may be a printed circuit board that includes various electronic components to process the information. The formatter can route information to the appropriate component area to execute the function for a particular print job. For example, the printer may be a multi-function printer with copy, fax, and print capabilities.

### BRIEF DESCRIPTION OF THE DRAWINGS

FIG. 1 is a block diagram of a multi-function device with a formatter having co-located right angle and vertical connector pads of the present disclosure;

FIG. 2 is a top view of an example formatter of the present disclosure;

FIG. 3 is a top view of an example right angle connector; and

FIG. 4 is a top view of an example formatter with a right angle connector of the present disclosure.

### DETAILED DESCRIPTION

Examples described herein provide a formatter with co-located right angle and vertical connector pads. As noted above, printers can include a formatter that is used to process information. A right angle connector or a vertical connector may be used to connect the formatter when the printer is installed. In some instances, there may not be enough room above the formatter so a right angle connector may be used. In some instances, there may not be enough room to the side of the formatter so a vertical connector may be used.

Currently, depending on the type of connector that is used, different formatters may be used. However, having different formatters may add to overall inventory costs and overhead. In some instances, the formatters may have the pads for the right angle connectors and vertical connectors in different locations. However, this may use additional surface area and cause the overall size of the formatter to be too large.

The present disclosure provides a formatter that has the right angle connector pads and the vertical connector pads located in the same area of the formatter. As a result, a single formatter may be used for right angle or vertical connectors, while maintaining a smaller overall size.

In addition, the right angle connectors may be designed to have a smaller fitting nail. The smaller fitting nail may fit in between the rows of connector pads used for vertical connectors. The smaller fitting nail may avoid touching the vertical connector pads and potentially causing a short on the formatter.

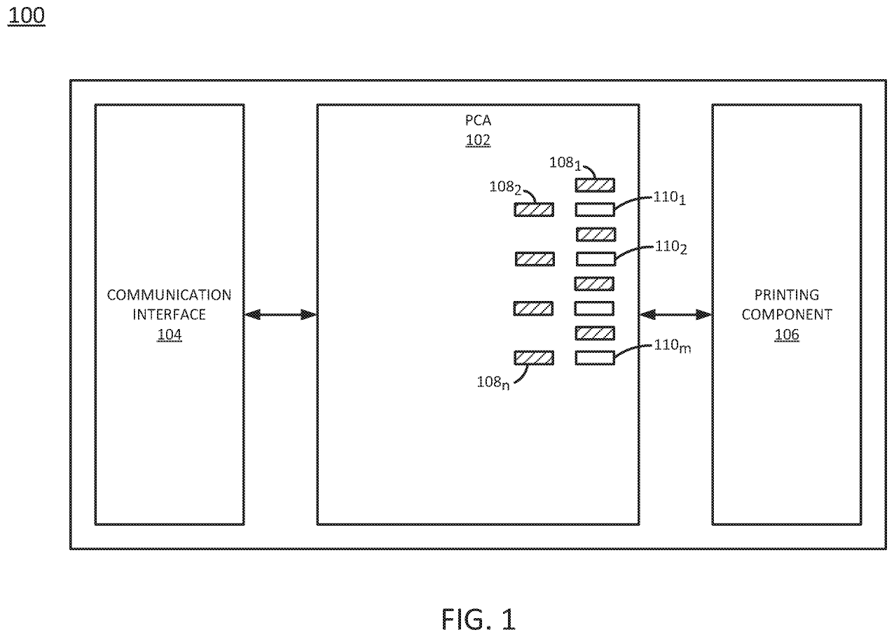

FIG. 1 illustrates an example multi-function device (MFD) 100 having a printed circuit assembly (PCA) 102 with co-located right angle and vertical connector pads of the present disclosure. In one example, the PCA 102 may be a formatter used in the MFD 100. It should be noted that the MFD 100 has been simplified for ease of explanation and may include additional components not shown (e.g., a toner, ink, printheads, digital front end, various paper paths, and the like).

In one example, the MFD 100 may include a communication interface 104 and a printing component 106 communicatively coupled to the PCA 102. In one example the PCA 102 may also be referred to as a formatter. A formatter may be a type of PCA that is used for printing devices. However, it should be noted that the PCA 102 of the present disclosure may be used for a variety of different electronic devices. In one example, the communication interface 104 may include a wired or wireless communication path to and from endpoint devices (not shown). The endpoint devices (e.g., a desktop computer, a laptop computer, a tablet computer, and the like) may transmit a print job to the MFD 100 via the communication interface 104. The print job may include various print data used by the MFD 100 to print a physical copy of the print job.

In one example, the communication interface 104 may transmit the print data to the PCA 102, which may then transmit the print data to the printing component 106. The printing component 106 may be communicatively coupled to the PCA 102 via a variety of different connectors. As noted above, different connectors would use different style formatters. As a result, a manufacturer may carry inventory of multiple different styles of formatters.

The present disclosure provides a PCA 102 that includes connector pads for both a vertical connector and a right angle connector. The PCA 102 may be a printed circuit board (PCB). The PCA 102 may include additional electronic components that are not shown. The PCA 102 illustrated in FIG. 1 is simplified for ease of explanation.

In one example, the PCA 102 may include a plurality of vertical connector pads 108₁ to 108ₙ (hereinafter also referred to individually as a vertical connector pad 108 or collectively as vertical connector pads 108). Within the same area of the vertical connector pads 108, the PCA 102 may also include right angle connector pads 110₁ to 110ₘ (hereinafter also referred to individually as a right angle connector pad 110 or collectively as right angle connector pads 110).

The vertical connector pads 108 may be arranged in two rows. The right angle connector pads 110 may be co-located with some of the vertical connector pads 108. For example, the right angle connector pads 110 may be located or positioned between the vertical connector pads 108 in a first row of the vertical connector pads 108. Some of the vertical connector pads 108 may also serve as a pad for a right angle connector. In other words, at least one row of connector pads may include different connector pads (e.g., vertical connector pads 108 and right angle connector pads 110) for two different types of connectors. As a result, a right angle connector may connect to the PCA 102 using some of the vertical connector pads 108 in the first row of the vertical connector pads 108 and the right angle connector pads 110. Alternatively, a vertical connector pad may connect to the vertical connector pads 108.

Notably, by having the vertical connector pads 108 and the right angle connector pads 110 co-located within a same area of the PCA 102, the overall size of the PCA 102 may be reduced. As a result, the overall size of the MFD 100 may also be reduced. In addition, as discussed in further details below, the vertical connector pads 108 and the right angle connector pads 110 are arranged to prevent connector pins of a particular type of connector from contacting the wrong pads.

In one example, after the PCA 102 processes the print data received from the communication interface 104, the PCA 102 may transmit the processed print data to the printing component 106. The printing component 106 may be a printer or a printing portion of the MFD 100. The printing component 106 may then control various print heads and paper print paths to print the print data onto a print medium (e.g., dispensing ink, toner, or other printing material, onto paper in accordance with a design or pattern defined by the print data).

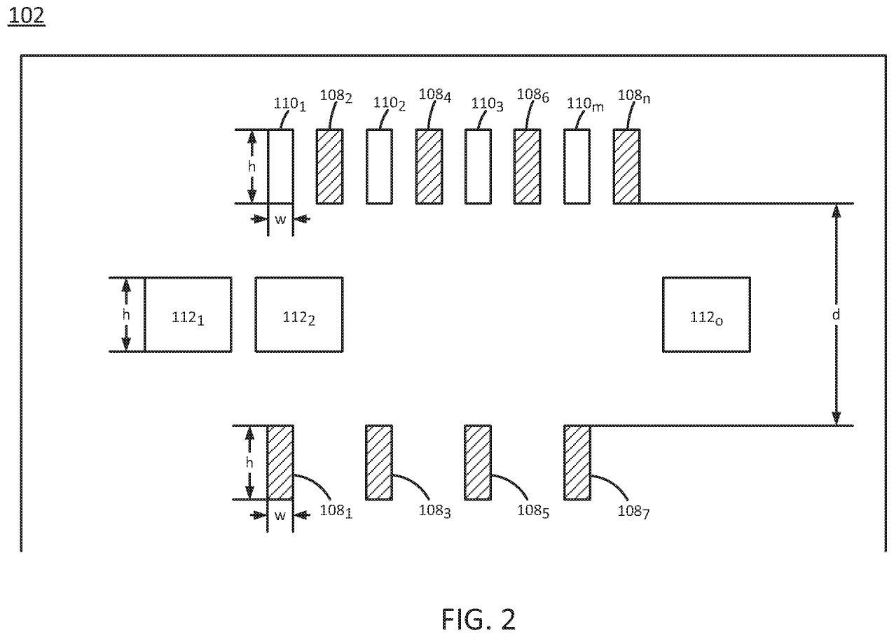

FIG. 2 illustrates a more detailed block diagram of the PCA 102. In one example, the PCA 102 may include a first row of the vertical connector pads 108 and a second row of the vertical connector pads 108. In one example, the right angle connector pads 110 may be located between the adjacent vertical connector pads of the first row of vertical connector pads 108.

Said another way, the first row of the vertical connector pads 108 may be offset horizontally from the second row of vertical connector pads 108. In other words, vertical connector pads of the first row of the vertical connector pads 108 may be aligned with spaces located between vertical connector pads of the second row of the vertical connector pads 108. The right angle connector pads 110 may be aligned vertically with vertical connector pads of the second row of the vertical connector pads 108. For example, the right angle connector pad 110₁ may be vertically aligned with the vertical connector pad 108₁, the right angle connector pad 110₂ may be vertically aligned with the vertical connector pad 108₃, and so forth.

The first row of the vertical connector pads 108₂, 108₄, 108₆, and 108ₙ may also serve as connector pads for the right angle connector. Thus, some of the vertical connector pads 108₂, 108₄, 108₆, and 108ₙ may also contact pins of the right angle connector along with the right angle connector pads 110.

In one example the vertical connector pads 108 and the right angle connector pads 110 may have identical, or approximately the same, dimensions. In other words, the height “h” and the width “w” of the vertical connector pads 108 and the right angle connector pads 110 may be approximately the same. The dimensions may be identical within a tolerance value (e.g., within several hundredths of millimeters).

In one example, the first row of the vertical connector pads 108 and the right angle connector pads 110 may be spaced apart from the second row of vertical connector pads 108 by a distance “d”. The distance “d” may be sufficient to allow space for fitting nails 112₁ to 112ₒ (hereinafter also referred to individually as a fitting nail 112 or collectively as fitting nails 112). In other words, the distance “d” between the first row and the second row of vertical connector pads 108 may correspond to a height “h” of the fitting nails 112. The distance “d” may also be sufficient to prevent connector pins of a right angle connector from contacting any portion of the second row of vertical connector pads 108 (e.g., vertical connector pads 108₁, 108₃, 108₅, and 108₇).

The fitting nails 112 may provide an area for contact with corresponding tabs on the right angle connector. In one example, the height “h” of the fitting nails 112 may be reduced to allow a smaller right angle connector design and allow sufficient space for both the vertical connector pads 108 and the right angle connector pads 110.

The fitting nails 112₁ to 112ₒ may be spaced apart (e.g., from left to right) on a common, or same, line to accommodate a plurality of different right angle connectors. In other words, the fitting nails 112₁ to 112ₒ may be aligned horizontally. For example, the fitting nail 112₁ may be located on a first end outside of the vertical connector pads 108 and the right angle connector pads 110 and a second fitting nail 112ₒ may be located on a second end of the vertical connector pads 108 and the right angle connector pads 110, as shown in FIG. 2. Another fitting nail 112₂ may be located to the right of the fitting nail 112₁ between the first row and the second row of the vertical connector pads 108. Thus, the fitting nail 112₁ and 112ₒ may accommodate one size of right angle connector and the fitting nail 112₂ and 112ₒ may accommodate a different size right angle connector (e.g., a smaller right angle connector with less contact pins).

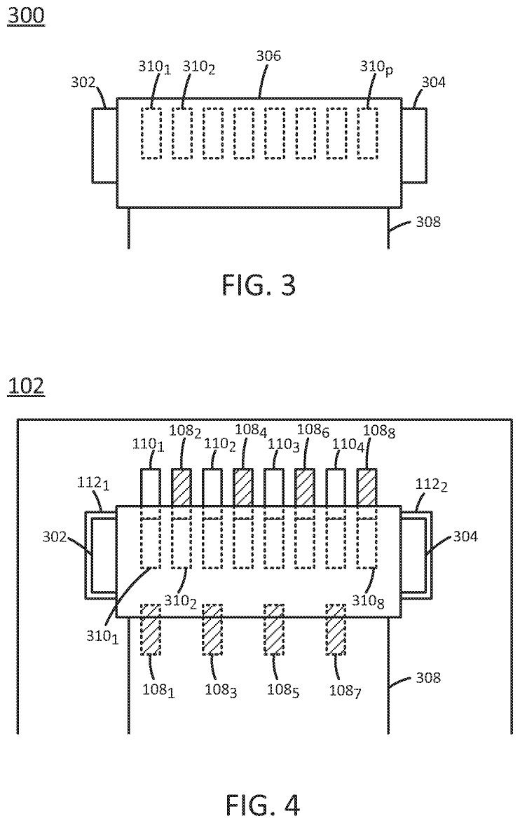

FIG. 3 illustrates an example of a right angle connector 300. The right angle connector 300 may include a body 306 having tabs or corresponding fitting nails 302 and 304 to secure the right angle connector 300 to the PCA 102. The tabs 302 and 304 may be located on opposite sides (e.g., opposite sides along a longest dimension of the right angle connector 300) of the body 306.

The right angle connector 300 may also include connector pins 310₁ to 310ₚ (hereinafter also referred to individually as a connector pin 310 or collectively as connector pins 310) that are illustrated in dashed lines indicating they are below the body 306. The connector pins 310 may be fabricated from a conductive metal. The connector pins 310 may be sized to fit within the dimensions of the right angle connector pads 110 and the first row of vertical connector pads 108.

FIG. 4 illustrates an example of the right angle connector 300 connected to the PCA 102. In one example, the right angle connector 300 may have eight connector pins 310. The corresponding fitting nail 302 may be coupled to the fitting nail 112₁ and the corresponding fitting nail 304 may be coupled to the fitting nail 112₂. The fitting nails 302 and 304 of the right angle connector may be sized to avoid contact with the second row of vertical connector pads 108 (e.g., vertical connector pads 108₁, 108₃, 108₅, and 108₇).

The connector pins 310₁ to 310₈ may contact a respective right angle connector pad (e.g., right angle connector pads 110₁-110₄) or a respective vertical connector pad in the first row (e.g., vertical connector pads 108₂, 108₄, 108₆, and 108₈).

Similarly, if a vertical connector were used, the connector pins of the vertical connector may contact the vertical connector pads 108₁-108₈ without contacting the right angle connector pads 110 or the fitting nails 112. Thus, the PCA 102 of the present disclosure provides a single PCA design that includes vertical connector pads 108, right angle connector pads 110 and fitting nails 112 within a same area of the PCA 102. In other words, the right angle connector pads 110 are located between some of the vertical connector pads 108. In addition, the fitting nails 112 are located between the rows of the vertical connector pads 108. Thus, a single type of PCA 102 may be used and kept in inventory irrespective of the type of connector that is used in a printing device (e.g., either a right angle connector or a vertical connector).

It should be noted that the numbers of pads (e.g., the vertical connector pads 108 or the right angle connector pads 110) are provided as examples. The PCA 102 may have any number of vertical connector pads 108 or right angle connector pads 110 based on a number of connector pins on a particular type of connector (e.g., a vertical connector or a right angle connector).

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. A printed circuit assembly (PCA), comprising:
vertical connector pads, wherein the vertical connector pads comprise a first row of pads and a second row of pads; and
right angle connector pads, wherein the right angle connector pads comprise the first row of pads of the vertical connector pads and additional pads that are co-located between adjacent pads of the first row of pads of the vertical connector pads.

2. The PCA of claim 1, further comprising:
a plurality of fitting nail pads located between the first row of pads and the second row of pads.

3. The PCA of claim 2, wherein the plurality of fitting nail pads are spaced apart to accommodate a plurality of different right angle connectors.

4. The PCA of claim 1, wherein the vertical connector pads and the right angle connector pads are printed on a printed circuit board connected to a printer.

5. The PCA of claim 1, wherein a distance between the first row of pads and the second row of pads corresponds to a distance between rows of connector pins of a vertical connector.

6. The PCA of claim 5, wherein the distance between the first row of pads and the second row of pads corresponds to a height of a fitting nail of a right angle connector.

7. The PCA of claim 1, wherein dimensions of the vertical connector pads and the right angle connector pads are identical.

8. A printing device, comprising:
a communication interface to receive print data;
a printed circuit assembly (PCA) to process the print data for printing, wherein the PCA comprises:
vertical connector pads, wherein the vertical connector pads comprise a first row of pads and a second row of pads; and
right angle connector pads, wherein the right angle connector pads comprise the first row of pads of the vertical connector pads and additional pads that are co-located between adjacent pads of the first row of pads of the vertical connector pads; and
a printing component communicatively coupled to the PCA to print the print data processed by the PCA.

9. The printing device of claim 8, wherein the PCA further comprises:
a first fitting nail pad located on a first end outside of the vertical connector pads and the right angle connector pads; and
a second fitting nail pad located on a second end between the vertical connector pads and right angle connector pads.

10. The printing device of claim 9, wherein the first fitting nail and the second fitting nail are on a same line.

11. The printing device of claim 8, wherein the right angle connector pads are aligned vertically with the second row of pads of the vertical connector pads.

12. The printing device of claim 8, wherein the first row of pads of the vertical connector pads are offset horizontally relative to the second row of the vertical connector pads.

13. The printing device of claim 12, wherein each pad of the first row of pads of the vertical connector pads aligns with a space between each pad of the second row of pads.

14. A formatter, comprising:
vertical connector pads, wherein the vertical connector pads comprise a first row of pads and a second row of pads;
right angle connector pads, wherein the right angle connector pads comprise the first row of pads of the vertical connector pads and additional pads located between adjacent pads of the first row of pads of the vertical connector pads;
fitting nail pads located between the first row of pads and the second row of pads; and
a right angle connector connected to the right angle connector pads, wherein the right angle connector comprises fitting nails that correspond to the location of the fitting nail pads and do not touch the second row of pads of the vertical connector pads.

15. The formatter of claim 14, wherein the fitting nail pads are located at different locations between the first row of pads and the second row of pads to accommodate different right angle connectors.
